(19) United States
(12) Patent Application Publication
(10) Pub. No.: US 2023/0384431 A1
(43) Pub. Date: Nov. 30, 2023

(54) LIGHT RECEIVING DEVICE AND DISTANCE MEASURING APPARATUS

(71) Applicant: Sony Semiconductor Solutions Corporation, Kanagawa (JP)

(72) Inventor: Jun Ogi, Kanagawa (JP)

(21) Appl. No.: 18/044,827

(22) PCT Filed: Sep. 13, 2021
(86) PCT No.: PCT/JP2021/033577

§ 371 Date: Mar. 10, 2023

(30) Foreign Application Priority Data
Oct. 27, 2020 (JP) 2020-179608

(51) Int. Cl. G01S 7/4863; G01S 17/10

(52) U.S. Cl. CPC G01S 7/4863; G01S 17/10; G01S 17/931

(57) ABSTRACT

A light receiving device according to an embodiment of the present disclosure includes a stacked chip structure including a pixel chip and a circuit chip that are stacked. In the pixel chip, a light receiving element is provided. The light receiving element generates a signal in accordance with reception of a photon. In the circuit chip, a circuit section that is included in a readout circuit is disposed along a direction perpendicular to a substrate surface of the circuit chip with respect to an electrical coupling section between the pixel chip and the circuit chip. The readout circuit reads the signal generated by the light receiving element.

### TECHNICAL FIELD

The present disclosure relates to a light receiving device and a distance measuring apparatus.

### BACKGROUND ART

There is a light receiving device (a photodetection device) that uses, as a light receiving element (a photodetection element), an element that generates a signal in accordance with reception of a photon. For example, a SPAD (Single Photon Avalanche Diode: single-photon avalanche diode) element is known as the light receiving element that generates a signal in accordance with reception of a photon.

Regarding a light receiving device that uses the SPAD element as the light receiving element, there is a concern that an opening rate of pixels decreases because a readout circuit such as a quench circuit, a pulse shaping circuit, or a counter circuit is needed for each pixel. To address such a concern, there is a technique that achieves an increase in the opening rate of the pixels by achieving Cu—Cu junction between the readout circuit such as the quench circuit, the pulse shaping circuit, or the counter circuit and the SPAD element for each pixel (for example, see PTL 1).

### CITATION LIST

### Patent Literature

PTL 1: US Unexamined Patent Application Publication No. 2018/0308881

### SUMMARY OF THE INVENTION

Incidentally, in a case of adopting a technique of stacking a transistor circuit section immediately above a pixel with use of a SOI (Silicon on Insulator) wafer in order to reduce the area of a readout circuit such as a quench circuit, a pulse shaping circuit, or a counter circuit, a large-aspect via (VIA) for connecting the SOI and the pixel to each other is needed. However, the use of the large-aspect via increases capacitance of a junction section between semiconductor chips, which leads to an issue that electric power consumption increases.

It is therefore desirable to provide a light receiving device that makes it possible to reduce electric power consumption by reducing capacitance of a junction section between semiconductor chips in a stacked chip structure including semiconductor chips (semiconductor substrates) that are stacked, and to provide a distance measuring apparatus that includes the light receiving device.

A light receiving device according to an embodiment of the present disclosure includes a stacked chip structure including a pixel chip and a circuit chip that are stacked. In the pixel chip, a light receiving element is provided. The light receiving element generates a signal in accordance with reception of a photon. In the circuit chip, a circuit section that is included in a readout circuit is disposed along a direction perpendicular to a substrate surface of the circuit chip with respect to an electrical coupling section between the pixel chip and the circuit chip. The readout circuit reads the signal generated by the light receiving element.

A distance measuring apparatus according to an embodiment of the present disclosure includes a light source unit and a light receiving device. The light source unit applies light to a distance measurement target. The light receiving device receives reflected light from the distance measurement target. The reflected light is based on the light applied from the light source unit. The light receiving device includes a stacked chip structure including a pixel chip and a circuit chip that are stacked. In the pixel chip, a light receiving element is provided. The light receiving element generates a signal in accordance with reception of a photon. In the circuit chip, a circuit section that is included in a readout circuit is disposed along a direction perpendicular to a substrate surface of the circuit chip with respect to an electrical coupling section between the pixel chip and the circuit chip. The readout circuit reads the signal generated by the light receiving element.

### BRIEF DESCRIPTION OF DRAWINGS

FIG. 1 is a schematic configuration diagram illustrating an example of a distance measuring apparatus to which the technology according to the present disclosure is applied.

FIG. 2A and FIG. 2B are block diagrams each illustrating an example of a specific configuration of a distance measuring apparatus according to the present application example.

FIG. 3 is a circuit diagram illustrating an example of a configuration of a basic pixel circuit using a SPAD element as a light receiving element.

FIG. 4A is a characteristic diagram illustrating a current-voltage characteristic of a PN junction of the SPAD element, and FIG. 4B is a waveform diagram for describing a circuit operation of the pixel circuit.

FIG. 5 is a sectional view of an example of a pixel structure according to a reference example.

FIG. 6 is a sectional view of an example of a pixel structure according to Embodiment 1.

FIG. 7 is an equivalent circuit diagram of a pixel having the pixel structure according to Embodiment 1.

FIG. 8 is an equivalent circuit diagram of a pixel having a pixel structure according to Embodiment 2.

FIG. 9 is a sectional view of an example of a pixel structure according to Embodiment 3.

FIG. 10 is an equivalent circuit diagram of a pixel having the pixel structure according to Embodiment 3.

FIG. 11 is a sectional view of an example of a pixel structure according to Embodiment 4.

FIG. 12 is a sectional view of an example of a pixel structure according to Embodiment 5.

FIG. 13 is a sectional view of an example of a pixel structure according to Embodiment 6.

FIG. 14 is an equivalent circuit diagram of a pixel having the pixel structure according to Embodiment 6.

FIG. 15 is an exploded perspective view of an example of a stacked chip structure according to Embodiment 7.

FIG. 16 is a circuit diagram illustrating an example of pixel sharing according to Embodiment 7.

FIG. 17 is a block diagram depicting an example of schematic configuration of a vehicle control system.

FIG. 18 is a diagram of assistance in explaining an example of installation positions of an outside-vehicle information detecting section and an imaging section.

### MODES FOR CARRYING OUT THE INVENTION

In the following, modes for carrying out the technology according to the present disclosure (hereinafter referred to as “embodiments”) are described in detail with reference to the drawings. The technology according to the present disclosure is not limited to the embodiments and, for example, various numerical values, materials, and the like in the embodiments are examples. In the following description, the same components or components having the same function are denoted by the same reference signs, and redundant description is omitted.

It is to be noted that the description is given in the following order.
1. General Description of Light Receiving Device and Distance Measuring Apparatus of Present Disclosure
2. Distance Measuring Apparatus to Which Technology According to Present Disclosure is Applied
   2-1. Specific Configuration Example of Distance Measuring Apparatus
   2-2. Basic Pixel Circuit Example Using SPAD Element as Light Receiving Element
   2-3. Circuit Operation Example of Pixel Circuit Using SPAD Element as Light Receiving Element
   2-4. Pixel Structure Example According to Reference Example
3. Light Receiving Device According to Embodiment of Present Disclosure
   3-1. Embodiment 1 (An example in which a pulse shaping circuit and a logic circuit are provided to be stacked in a circuit chip)
   3-2. Embodiment 2 (A modification of Embodiment 1: An example in which the pulse shaping circuit is provided together with the SPAD element and a quench circuit on a pixel chip side)
   3-3. Embodiment 3 (A modification of Embodiment 2: An example in which a resistive element is provided between the SPAD element, and the quench circuit and the pulse shaping circuit that are stacked in the pixel chip)
   3-4. Embodiment 4 (A modification of Embodiment 3: An example in which a contact section is provided in addition to the resistive element)
   3-5. Embodiment 5 (A modification of Embodiment 1: An example in which the contact section related to a pixel is directly electrically coupled to a transistor formation back surface side)
   3-6. Embodiment 6 (An example of a three-layered stacked structure in which the circuit chip includes two semiconductor chips)
   3-7. Embodiment 7 (An example in which one logic circuit on the circuit chip is shared by multiple pixels on the pixel chip in a stacked chip structure)
4. Modifications
5. Application Examples of Technology According to Present Disclosure (An example of a mobile body)
6. Possible Configurations of Present Disclosure

### <General Description of Light Receiving Device and Distance Measuring Apparatus of Present Disclosure>

In a light receiving device and a distance measuring apparatus of the present disclosure, it is possible to provide a configuration in which a light receiving element includes an avalanche photodiode that operates in a Geiger mode, preferably a single-photon avalanche diode (SPAD).

In the light receiving device and the distance measuring apparatus of the present disclosure including the preferable configuration described above, in a case where a readout circuit includes multiple transistor circuit sections, it is possible to provide a configuration in which the multiple transistor circuit sections are provided to be stacked on each other in the circuit chip. In a case where the multiple transistor circuit sections include a pulse shaping circuit shaping a pulse signal outputted from the light receiving element and a logic circuit processing the pulse signal shaped by the pulse shaping circuit, it is possible to provide a configuration in which the pulse shaping circuit and the logic circuit are provided to be stacked on each other in the circuit chip. In addition, in a case where a quench circuit suppressing avalanche multiplication of the light receiving element is provided in the pixel chip, it is possible to provide a configuration in which the quench circuit is provided to be stacked with respect to the light receiving element in the pixel chip.

In addition, in the light receiving device and the distance measuring apparatus of the present disclosure including the preferable configuration described above, in a case where the multiple transistor circuit sections include a pulse shaping circuit shaping a pulse signal outputted from the light receiving element and a logic circuit processing the pulse signal shaped by the pulse shaping circuit, it is possible to provide a configuration in which a quench circuit suppressing avalanche multiplication of the light receiving element and the pulse shaping circuit are provided to be stacked with respect to the light receiving element in the pixel chip, and the logic circuit is provided in the circuit chip.

In addition, in the light receiving device and the distance measuring apparatus of the present disclosure including the preferable configuration described above, it is possible to provide a configuration in which the electrical coupling section between the pixel chip and the circuit chip includes a junction section of direct junction using a Cu electrode. In addition, in a case where the circuit chip includes two semiconductor chips that are stacked, it is possible to provide a configuration in which the pulse shaping circuit is provided in one of the two semiconductor chips, and the logic circuit is provided in another of the two semiconductor chips.

In addition, in the light receiving device and the distance measuring apparatus of the present disclosure including the preferable configuration described above, in a case where an analogue circuit section including the quench circuit is provided in pixel units together with the light receiving element in the pixel chip, and a digital circuit section including the logic circuit is provided in the circuit chip, it is possible to provide a configuration in which the one digital circuit section on the circuit chip is shared by the analogue circuit section for multiple pixels on the pixel chip.

Further, in the light receiving device and the distance measuring apparatus of the present disclosure including the preferable configuration described above, in a case where a side, of the pixel chip, on which a wiring layer is provided is regarded as a substrate front surface side, it is possible to provide a configuration in which a pixel including the light receiving element has a back-illuminated pixel structure that takes in light applied from a substrate back surface side.

### <Distance Measuring Apparatus to Which Technology According to Present Disclosure is Applied>

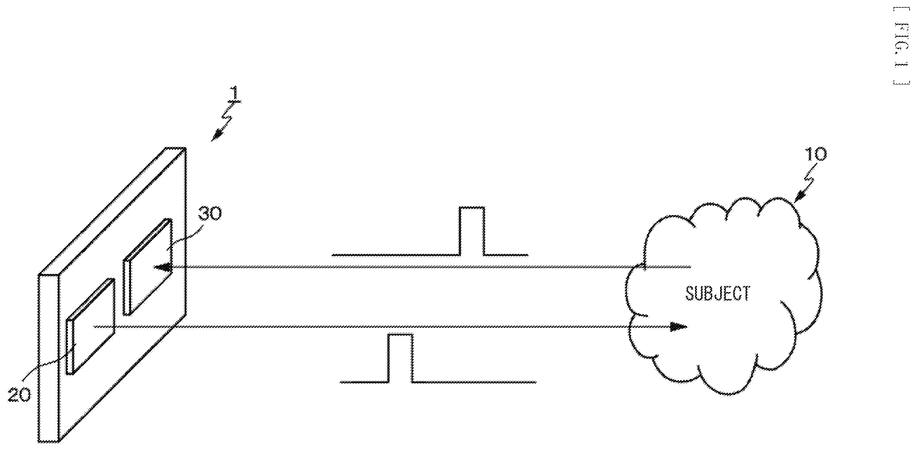

FIG. 1 is a schematic configuration diagram illustrating an example of a distance measuring apparatus to which the technology according to the present disclosure is applied (i.e., the distance measuring apparatus of the present disclosure).

A distance measuring apparatus 1 according to the present application example adopts a ToF (Time of Flight: time of flight) method as a measurement method for measuring a distance to a subject 10 that is a distance measurement target. The ToF method is a method of measuring a time of flight that is a time for light (e.g., laser light having a peak wavelength in an infrared wavelength region) applied toward the subject 10 to be reflected by the subject 10 and return. In order to achieve distance measurement by the ToF method, the distance measuring apparatus 1 according to the present application example includes a light source unit 20 and a light receiving device 30. As the light receiving device 30, it is possible to use a light receiving device according to an embodiment of the present disclosure to be described later.

### Specific Configuration Example of Distance Measuring Apparatus

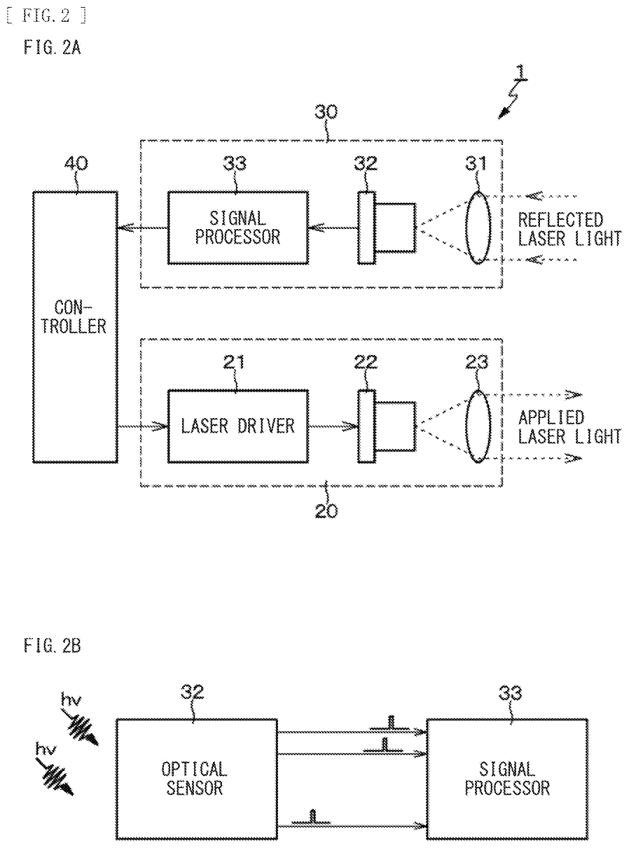

FIG. 2A and FIG. 2B each illustrate an example of a specific configuration of the distance measuring apparatus 1 according to the present application example. The light source unit 20 includes, for example, a laser driver 21, a laser light source 22, and a diffusion lens 23, and applies laser light to the subject 10. The laser driver 21 drives the laser light source 22 under a control performed by a controller 40. The laser light source 22 includes, for example, a laser diode, and emits laser light by being driven by the laser driver 21. The diffusion lens 23 diffuses the laser light emitted from the laser light source 22 and applies the diffused laser light to the subject 10.

The light receiving device 30 includes a light receiving lens 31, an optical sensor 32 that is a light receiving section, and a signal processor 33. The light receiving device 30 receives reflected laser light that is the laser light which is applied by the light source unit 20, is reflected by the subject 10, and returns. The light receiving lens 31 condenses the reflected laser light from the subject 10 onto a light receiving surface of the optical sensor 32. The optical sensor 32 receives, in pixel units, the reflected laser light from the subject 10 having passed through the light receiving lens 31 and performs photoelectric conversion on the received reflected laser light. As the optical sensor 32, it is possible to use a two-dimensional array sensor. The two-dimensional array sensor includes pixels that include light receiving elements and are two-dimensionally arranged in a matrix (in an array).

An output signal of the optical sensor 32 is supplied to the controller 40 via the signal processor 33. The controller 40 includes, for example, a CPU (Central Processing Unit: central processing unit) or the like. The controller 40 controls the light source unit 20 and the light receiving device 30, and measures a time for the laser light applied from the light source unit 20 toward the subject 10 to be reflected by the subject 10 and return. It is possible to determine the distance to the subject 10 on the basis of this measured time.

As a method for time measurement, a timer is started at a timing when the light source unit 20 applies pulse light and the timer is stopped at a timing when the light receiving device 30 receives the pulse light to thereby measure the time. As another method for time measurement, pulse light may be applied from the light source unit 20 at a predetermined cycle, the cycle at which the light receiving device 30 receives the pulse light may be detected, and the time may be measured from a phase difference between the cycle of light emission and the cycle of light reception. The time measurement is executed multiple times, and the time is measured by detecting a position of a peak of a ToF histogram in which the times measured multiple times are accumulated.

In addition, in the distance measuring apparatus 1 according to the present application example, a sensor in which the light receiving element of the pixel includes an element that generates a signal in accordance with reception of a photon, such as a SPAD (Single Photon Avalanche Diode: single-photon avalanche diode) element, is used as the optical sensor 32. In other words, the light receiving device 30 in the distance measuring apparatus 1 according to the present application example has a configuration in which the SPAD element is used as the light receiving element of the pixel. The SPAD element is a kind of avalanche photodiode having light reception sensitivity that is increased with use of a phenomenon called avalanche multiplication. The SPAD element operates in a Geiger mode in which the element is caused to operate with a backward voltage that is beyond a breakdown voltage (a breakdown voltage).

It is to be noted that although the SPAD element has been described here as an example of the light receiving element (a photodetection element) of the pixel, the light receiving element is not limited to the SPAD element. That is, as the light receiving element of the pixel, it is possible to use any of various elements that operate in the Geiger mode, such as an APD (avalanche photodiode) or a SiPM (silicon photomultiplier), other than the SPAD element.

### Basic Pixel Circuit Example Using SPAD Element as Light Receiving Element

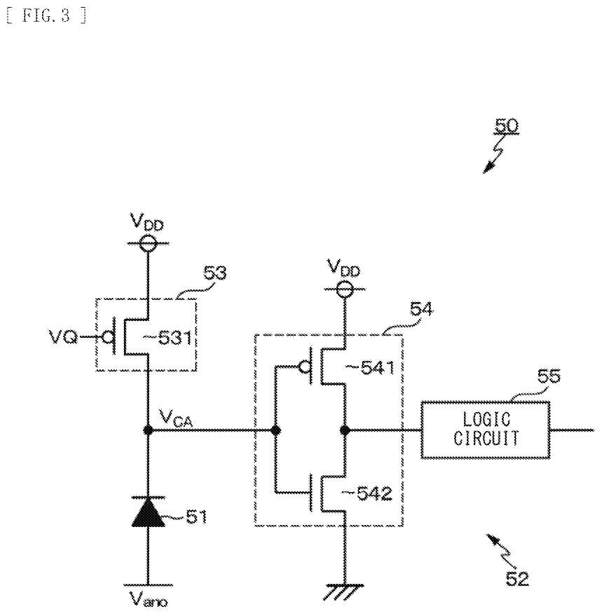

FIG. 3 illustrates an example of a configuration of a basic pixel circuit in the light receiving device 30 using the SPAD element as the light receiving element. A basic pixel circuit example for one pixel is illustrated here.

A pixel 50 of the light receiving device 30 has a configuration including a SPAD element 51 and a readout circuit 52. The SPAD element 51 is the light receiving element. The readout circuit 52 is coupled to a cathode electrode of the SPAD element 51 and reads a signal generated by the SPAD element 51. That is, the signal generated by the SPAD element 51 in accordance with reception of a photon is read as a cathode potential VCA by the readout circuit 52.

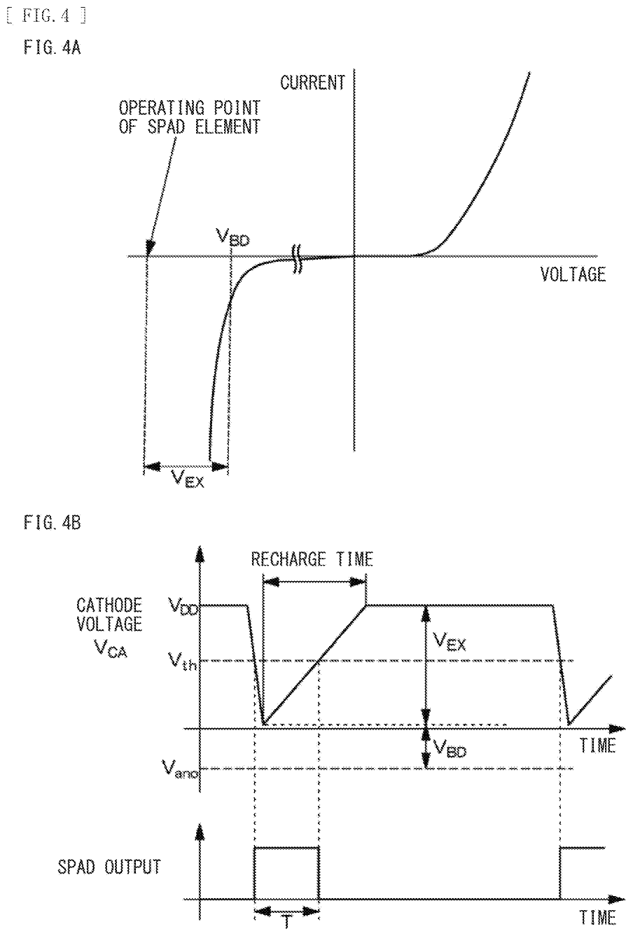

An anode voltage Vano is applied to an anode electrode of the SPAD element 51. As the anode voltage Vano, a large negative voltage that causes avalanche multiplication, that is, a voltage (e.g., about −20 V) higher than or equal to the breakdown voltage is applied (see FIG. 4B).

The readout circuit 52 includes, for example, multiple transistor circuit sections including a quench circuit 53, a pulse shaping circuit 54, a logic circuit 55, and the like.

The quench circuit 53 is a circuit that suppresses avalanche multiplication of the SPAD element 51. The quench circuit 53 includes, for example, a transistor circuit section that includes a quench transistor 531 including a P-type MOS transistor. The quench transistor 531 has a gate electrode to which a quench control voltage VQ is applied. The quench transistor 531 is controlled to have a constant current value by the quench control voltage VQ applied to the gate electrode, and suppresses the avalanche multiplication of the SPAD element 51 by controlling a current flowing through the SPAD element 51.

The pulse shaping circuit 54 includes, for example, a transistor circuit section including a CMOS inverter circuit that includes a P-type MOS transistor 541 and an N-type MOS transistor 542. The pulse shaping circuit 54 detects a reaction edge of the SPAD element 51. A pulse signal shaped by the pulse shaping circuit 54 is supplied to the logic circuit 55 in a subsequent stage.

The logic circuit 55 includes, for example, a counter circuit configured with use of a transistor, a TDC (Time-to-Digital Converter: time measurement) circuit, or the like. The TDC circuit measures a time for light applied toward a measurement target to be reflected by the measurement target and return, on the basis of an SPAD output, that is, an output pulse of the pulse shaping circuit 54. It is to be noted that the logic circuit 55 includes the TDC circuit in some cases, and includes the counter circuit in other cases.

As describe above, a voltage (e.g., about −20 V) higher than or equal to a breakdown voltage VBD is applied to the SPAD element 51. An excess voltage higher than or equal to the breakdown voltage VBD is called an excess bias voltage VEX. Characteristics of the SPAD element 51 change depending on how high the voltage value of the applied excess bias voltage VEX is with respect to the voltage value of the breakdown voltage VBD.

FIG. 4A illustrates an I (current)-V (voltage) characteristic of a PN junction of the SPAD element 51 that operates in the Geiger mode. FIG. 4A illustrates a relationship between the breakdown voltage VBD, the excess bias voltage VEX, and an operating point of the SPAD element 51.

### Circuit Operation Example of Pixel Circuit Using SPAD Element as Light Receiving Element

Next, a description is given of an example of a circuit operation of the pixel circuit having the configuration described above with reference to a waveform diagram in FIG. 4B.

In a state where no current is flowing through the SPAD element 51, a voltage having a value of (VDD−Vano) is applied to the SPAD element 51. This voltage value (VDD−Vano) is (VBD+VEX). Further, electrons generated at a PN junction section of the SPAD element 51 due to a dark electron generation rate DCR (Dark Count Rate) or light application cause avalanche multiplication to occur. As a result, an avalanche current is generated. Such a phenomenon stochastically occurs even in a light-blocked state (i.e., a state with no incidence of light). This is the dark electron generation rate, that is, the dark count rate DCR (Dark Count Rate).

In a case where the cathode potential VCA drops and a voltage between terminals of the SPAD element 51 becomes the breakdown voltage VBD of a PN diode, the avalanche current stops. Further, electrons generated due to the avalanche multiplication and accumulated perform discharge through a load 54 (e.g., a P-type MOS transistor QL), and the cathode potential VCA increases. Further, the cathode potential VCA is restored to a power supply voltage VDD, and returns to an initial state again.

In a case where light enters the SPAD element 51 and even a single electron-hole pair is generated, the pair becomes a source to generate an avalanche current. It is thus possible to detect the entry of even a single photon at certain detection efficiency PDE (Photon Detection Efficiency).

The above-described operations are repeated. In addition, in this series of operations, a waveform of the cathode potential VCA is shaped by a CMOS inverter 55, and a pulse signal having a pulse width T with the arrival time of one photon as a start point becomes the SPAD output (a pixel output).

### Pixel Structure Example According to Reference Example Using SPAD Element as Light Receiving Element

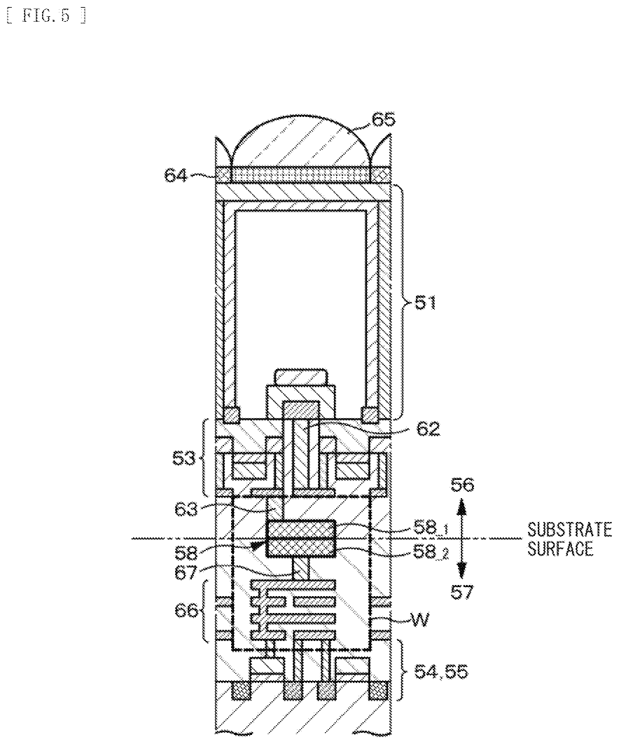

Here, a description is given of a pixel structure according to a reference example using the SPAD element 51 as the light receiving element. FIG. 5 is a sectional view of an example of the pixel structure according to the reference example.

The pixel 50 of the light receiving device 30 has a stacked chip structure in which a semiconductor chip (hereinafter, referred to as a “pixel chip”) 56 in which the SPAD element 51 is provided and a semiconductor chip (hereinafter, referred to as a “circuit chip”) 57 in which the readout circuit 52 is provided are stacked. The pixel chip 56 and the circuit chip 57 are electrically coupled to each other via an electrical coupling section, for example, a Cu—Cu junction section 58 of direct junction using Cu electrodes 58_1 and 58_2.

Here, a pixel structure in which the quench circuit 53 is provided on the pixel chip 56 is described as an example of the pixel structure according to the reference example. In the pixel chip 56, the SPAD element 51 and the quench circuit 53 are stacked and are electrically coupled to each other via a contact section 62. The quench circuit 53 is electrically coupled to the Cu electrode 58_1 of the Cu—Cu junction section 58 via a contact section 63. A color filter 64 is provided on the SPAD element 51, and a microlens 65 is provided on the color filter 64.

Here, in the pixel chip 56, in a case where a side on which a wiring layer 61, the quench circuit 53, and the like are provided is regarded as a substrate front surface side, a side on which the color filter 64 and the microlens 65 are provided is a substrate back surface side. The pixel structure according to the reference example thus has a back-illuminated pixel structure that takes in light applied from the substrate back surface side. This point similarly applies to each of Embodiments to be described later.

In the circuit chip 57, the pulse shaping circuit 54 and the logic circuit 55 are disposed side by side (in other words, disposed in a flat manner) in a direction parallel to a substrate surface, and an input end of the logic circuit 55 and an output end of the pulse shaping circuit 54 are electrically coupled to each other. In addition, the input end of the pulse shaping circuit 54 is electrically coupled to the Cu electrode 58_2 of the Cu—Cu junction section 58 via the wiring layer 66 and a contact section 67.

As described above, the pixel structure according to the reference example has a configuration in which the pulse shaping circuit 54 and the logic circuit 55 are disposed side by side in the direction parallel to the substrate surface in the circuit chip 57. If the pulse shaping circuit 54 and the logic circuit 55 are disposed side by side in the direction parallel to the substrate surface as in the case of the pixel structure according to the reference example, a wiring structure of the wiring layer 66 that electrically couples the circuit chip 57 to the pixel chip 56 must be complicated. This increases the capacitance of the coupling section (a region W surrounded by a thick broken line in the drawing) including the Cu—Cu junction section 58, resulting in an increase in electric power consumption of the light receiving device 30.

### Light Receiving Device According to Embodiment of Present Disclosure

The light receiving device 30 according to the embodiment of the present disclosure has a pixel structure having a stacked chip structure including the pixel chip 56 and the circuit chip 57 that are stacked. In such a pixel structure, the light receiving device 30 according to the embodiment of the present disclosure has a configuration in which a transistor circuit section is disposed, in the circuit chip 57, along a direction perpendicular to a substrate surface of the circuit chip 57 with respect to an electrical coupling section between the pixel chip 56 and the circuit chip 57. The transistor circuit section is included in the readout circuit 52. In a case where multiple transistor circuit sections included in the readout circuit 52 are present, a structure in which the multiple transistor circuit sections are stacked on each other is achieved by disposing the multiple transistor circuit sections along the direction perpendicular to the substrate surface of the circuit chip 57. It is to be noted that the transistor circuit section to be disposed along the direction perpendicular to the substrate surface of the circuit chip 57 is not limited to the multiple transistor circuit sections, and the transistor circuit section may be one. Here, the meaning of the “direction perpendicular to” encompasses a case of being a direction substantially perpendicular in addition to a case of being a direction strictly perpendicular, and presence of various kinds of variation that occur due to a design or manufacturing is allowed.

By providing the configuration in which the transistor circuit section included in the readout circuit 52 is disposed, in the circuit chip 57, along the direction perpendicular to the substrate surface of the circuit chip 57 with respect to the electrical coupling section between the pixel chip 56 and the circuit chip 57 as described above, it is possible to simplify the wiring structure of the wiring layer 66 illustrated in FIG. 5, as compared with a case where the multiple transistor circuit sections are disposed side by side (disposed in a flat manner) in the direction parallel to the substrate surface. This makes it possible to reduce the capacitance of the coupling section between the pixel chip 56 and the circuit chip 57 and reduce the signal amplitude at and after the coupling section. It is therefore possible to reduce electric power consumption of the light receiving device 30. In the light receiving device 30 according to the embodiment of the present disclosure, examples of the multiple transistor circuit sections included in the readout circuit 52 are, for example, the quench circuit 53, the pulse shaping circuit 54, and the logic circuit 55.

In the following, a description is given of specific embodiments of the present embodiment for reducing the capacitance of the coupling section between the pixel chip 56 and the circuit chip 57 and reducing electric power consumption.

### Embodiment 1

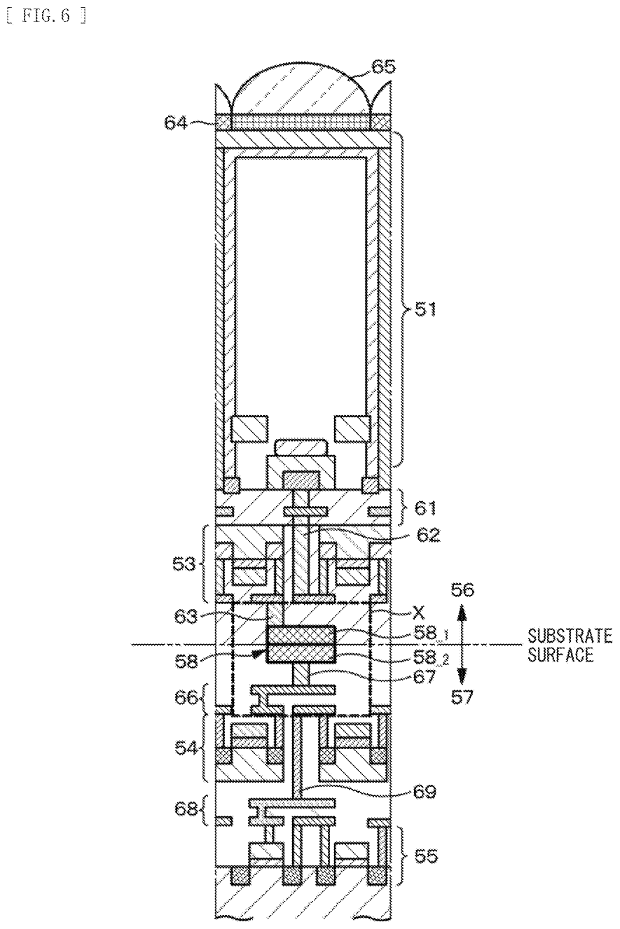

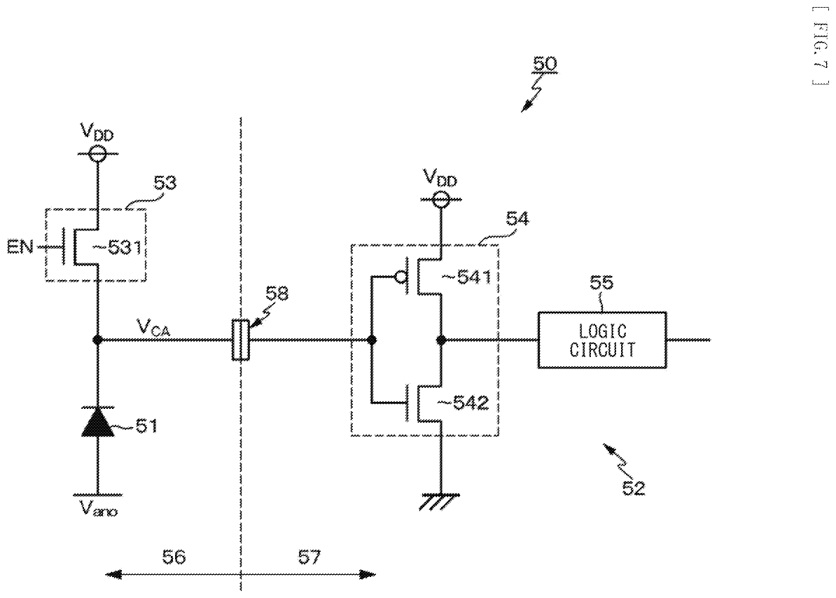

Embodiment 1 is an example in which the pulse shaping circuit 54 and the logic circuit 55 are provided to be stacked in the circuit chip 57. FIG. 6 illustrates a sectional view of an example of a pixel structure according to Embodiment 1. FIG. 7 illustrates an equivalent circuit diagram of a pixel having the pixel structure according to Embodiment 1.

The pixel structure according to Embodiment 1 has a two-layered stacked chip structure including the pixel chip 56 and the circuit chip 57 that are stacked. In such a two-layered stacked chip structure, the SPAD element 51 and the quench circuit 53 are disposed, in the pixel chip 56, along a direction (an upper-lower direction in the drawing) perpendicular to a substrate surface of the pixel chip 56. That is, a structure is provided in which the SPAD element 51 and the quench circuit 53 are stacked with the wiring layer 61 interposed therebetween in the direction perpendicular to the substrate surface of the pixel chip 56. The SPAD element 51 and the quench circuit 53 are electrically coupled to each other via the contact section 62. The quench circuit 53 is electrically coupled to the Cu electrode 58_1 of the Cu—Cu junction section 58 via the contact section 63. The color filter 64 is provided on the SPAD element 51, and the microlens 65 is provided on the color filter 64.

Meanwhile, in the circuit chip 57, the pulse shaping circuit 54, which includes a CMOS inverter circuit, and the logic circuit 55, which includes a counter circuit or a TDC circuit, are disposed along the direction (the upper-lower direction in the drawing) perpendicular to the substrate surface of the circuit chip 57. That is, a structure is provided in which the pulse shaping circuit 54 and the logic circuit 55 are stacked in the direction perpendicular to the substrate surface of the circuit chip 57. The pulse shaping circuit 54 and the logic circuit 55 are electrically coupled to each other via a wiring layer 68 and a contact section 69. The pulse shaping circuit 54 is electrically coupled to the Cu electrode 58_2 of the Cu—Cu junction section 58 via the wiring layer 66 and the contact section 67.

In addition, the pixel chip 56 and the circuit chip 57 are electrically coupled to each other via the Cu—Cu junction section 58 which is the electrical coupling section. Specifically, a structure is provided in which a front surface side (a front surface side of the SPAD element 51) of the pixel chip 56 and a transistor formation back surface side of the circuit chip 57 are opposed to each other and bonded to each other (so-called Face to Back).

As described above, the pixel structure according to Embodiment 1 has the two-layered stacked chip structure including the pixel chip 56 and the circuit chip 57 that are stacked. In such a two-layered stacked chip structure, a three-dimensional stacked structure is provided in which the SPAD element 51 and the quench circuit 53 are stacked in the pixel chip 56 and the pulse shaping circuit 54 and the logic circuit 55 are stacked in the circuit chip 57. The use of the three-dimensional stacked structure as described above makes it possible to reduce the footprint of the readout circuit 52. In addition, stacking the transistors included in the quench circuit 53, the pulse shaping circuit 54, and the like between each wiring layer and a chip junction surface makes it possible to allow for wiring above and below the stacked transistors. This makes it possible to improve wiring efficiency and to reduce the circuit area.

In addition, the circuit chip 57 in particular has the structure in which the pulse shaping circuit 54 and the logic circuit 55 are disposed along the direction perpendicular to the substrate surface of the circuit chip 57 and are stacked. This makes it possible to simplify the wiring structure of the wiring layer 66 that electrically couples the circuit chip 57 to the pixel chip 56. This makes it possible to reduce the capacitance of the coupling section (a region X surrounded by a thick broken line in the drawing) including the Cu—Cu junction section 58 and to reduce the signal amplitude at and after the coupling section. It is therefore possible to reduce electric power consumption of the light receiving device 30.

In addition, using the three-dimensional stacked structure for the pixel chip 56 makes it possible to mount the quench circuit 53 in the pixel chip 56 without changing an opening rate of the pixel 50 including the SPAD element 51. This makes it possible to reduce circuit components to be integrated in the circuit chip 57. In addition, using the three-dimensional stacked structure for the circuit chip 57 makes it possible to stack a portion of a component such as a digital counter included in the logic circuit 55, and to thereby reduce the total footprint.

### Embodiment 2

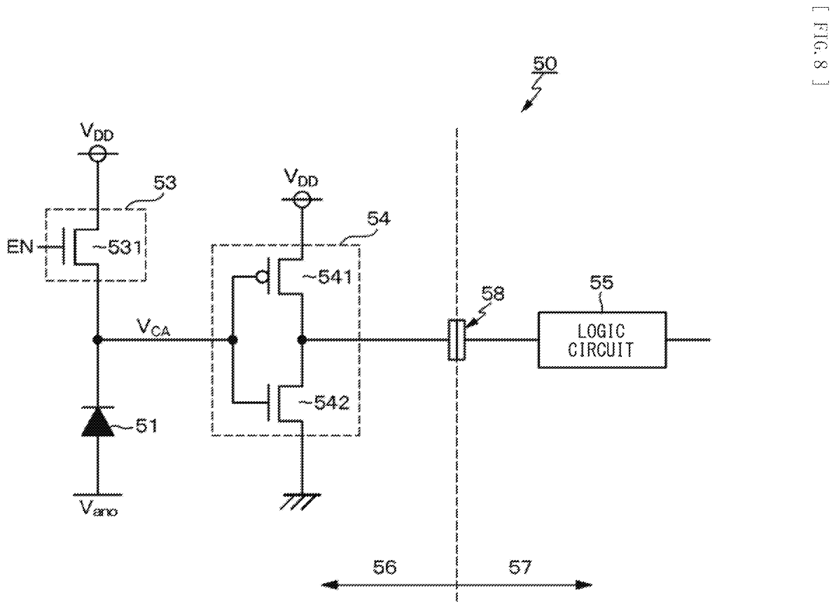

Embodiment 2 is a modification of Embodiment 1. Embodiment 2 is an example in which the pulse shaping circuit 54 is provided on the side of the pixel chip 56 together with the SPAD element 51 and the quench circuit 53. FIG. 8 illustrates an equivalent circuit diagram of a pixel having a pixel structure according to Embodiment 2.

The pixel structure according to Embodiment 1 has the configuration in which the SPAD element 51 and the quench circuit 53 are provided on the side of the pixel chip 56. Meanwhile, the pixel structure according to Embodiment 2 has a configuration in which the pulse shaping circuit 54 is provided on the side of the pixel chip 56 together with the SPAD element 51 and the quench circuit 53. Accordingly, in the pixel structure according to Embodiment 2, the transistor circuit section included in the readout circuit 52 provided on the side of the circuit chip 57 is only the logic circuit 55 (only one).

In the pixel structure according to Embodiment 2 also, the one logic circuit 55 is disposed along the direction perpendicular to the substrate surface of the circuit chip 57. As with the case of Embodiment 1, this makes it possible to simplify the wiring structure (see FIG. 6) of the wiring layer 66 that electrically couples the circuit chip 57 to the pixel chip 56. As a result, it is possible to reduce the capacitance of the coupling section including the Cu—Cu junction section 58 and to reduce the signal amplitude at and after the coupling section. It is therefore possible to reduce electric power consumption of the light receiving device 30.

In addition, in the pixel structure according to Embodiment 2, the pixel chip 56 has a three-dimensional stacked structure in which the SPAD element 51, the quench circuit 53, and the pulse shaping circuit 54 are stacked. Using the three-dimensional stacked structure as described above makes it possible to achieve an effect of reducing the footprint of the readout circuit 52. In addition, using the three-dimensional stacked structure makes it possible to mount the quench circuit 53 and the pulse shaping circuit 54 in the pixel chip 56 without changing the opening rate of the pixel 50 including the SPAD element 51. This makes it possible to reduce circuit components to be integrated in the circuit chip 57.

### Embodiment 3

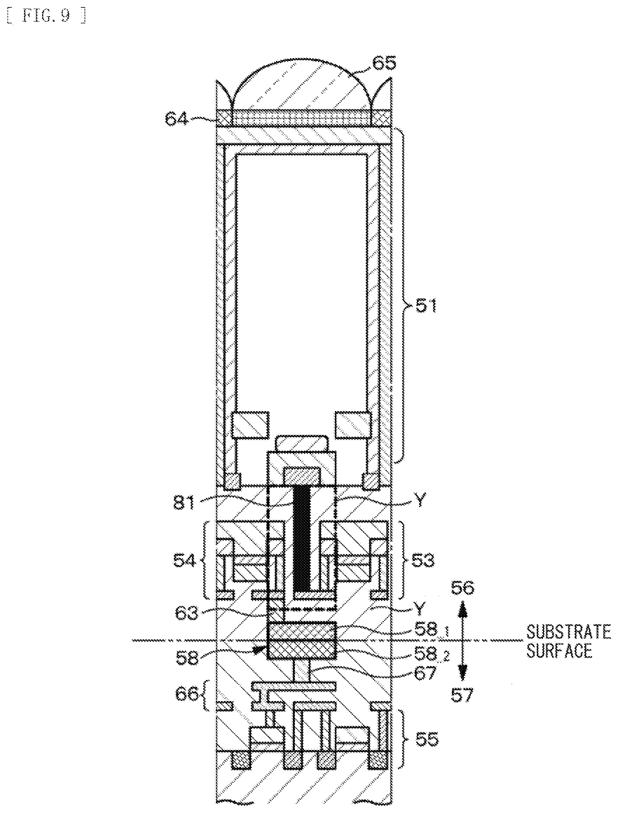

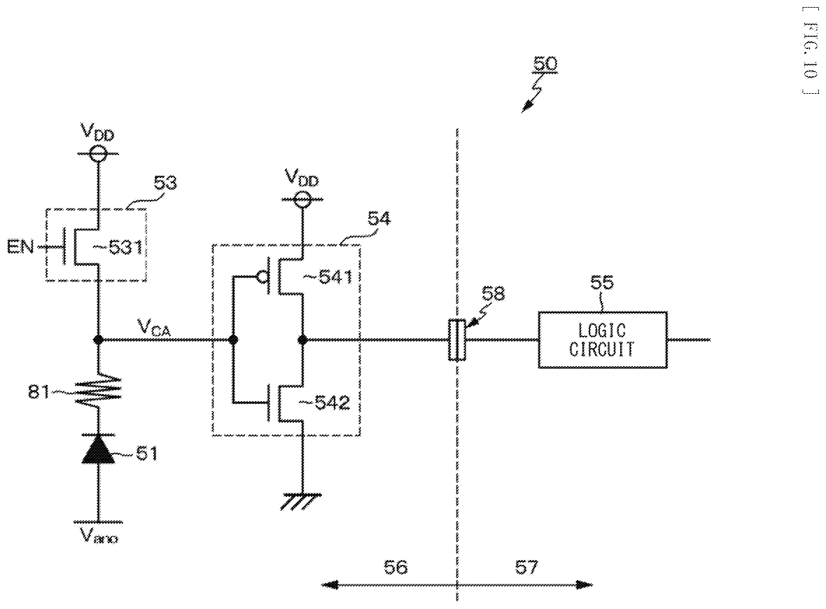

Embodiment 3 is a modification of Embodiment 2. Embodiment 3 is an example in which, in the pixel chip 56, a resistive element is provided between the SPAD element 51, and the quench circuit 53 and the pulse shaping circuit 54 that are stacked. FIG. 9 illustrates a sectional view of an example of a pixel structure according to Embodiment 3. FIG. 10 illustrates an equivalent circuit diagram of a pixel having the pixel structure according to Embodiment 3.

The pixel structure according to Embodiment 3 has, on the side of the pixel chip 56, a three-dimensional stacked structure in which the SPAD element 51, the quench circuit 53, and the pulse shaping circuit 54 are stacked. In such a three-dimensional stacked structure, a configuration is provided in which a resistive element 81 is electrically coupled between the SPAD element 51, and the quench circuit 53 and the pulse shaping circuit 54. As the resistive element 81, a polysilicon diffusion resistive element, a high-resistance metal element, or the like is usable.

Providing the resistive element 81 between the SPAD element 51, and the quench circuit 53 and the pulse shaping circuit 54 in the three-dimensional stacked structure on the side of the pixel chip 56 as described above makes it possible to completely separate the capacitance of a pixel section (a region Y surrounded by a thick broken line in the drawing) between the side of the SPAD element 51 and the side of the quench circuit 53 and the pulse shaping circuit 54 owing to the working of the resistive element 81. It is therefore possible to further reduce electric power consumption of the light receiving device 30, as compared with the case of Embodiment 2.

It is to be noted that although FIG. 9 illustrates, as an example, a structure (so-called Face to Back) in which the front surface side of the SPAD element 51 and a back surface side of the provided transistor included in the quench circuit 53 and the pulse shaping circuit 54 are opposed to each other for stacking in the three-dimensional stacked structure on the side of the pixel chip 56, it is possible to provide the resistive element 81 also in a case where the front surface side of the SPAD element 51 and the transistor formation front surface side are opposed to each other for stacking (so-called Face to Face).

In the case (Face to Back) where the front surface side of the SPAD element 51 and the transistor formation back surface side are opposed to each other for stacking, generally, the transistor is formed after stacking a silicon wafer on the pixel 50. Accordingly, heat for forming the transistor influences the pixel 50, the resistive element 81 below the pixel 50, and the like. It is therefore necessary to make the resistive element 81, taking into consideration such heat.

In contrast, in the case (Face to Face) where the front surface side of the SPAD element 51 and the transistor formation front surface side are opposed to each other for stacking, wafers are often bonded to each other after the formation of the transistor is completed. It is therefore possible to suppress an influence of the excess heat applied to the resistive element 81. This allows for easier device designing for the resistive element 81.

### Embodiment 4

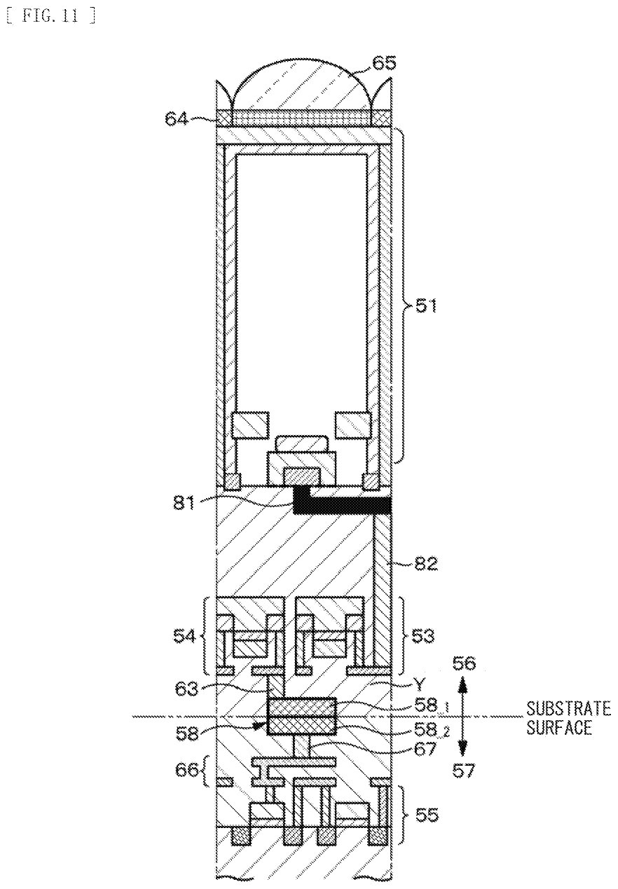

Embodiment 4 is a modification of Embodiment 3. Embodiment 4 is an example in which, in the pixel chip 56, a contact section is provided, in addition to the resistive element, between the SPAD element 51, and the quench circuit 53 and the pulse shaping circuit 54 that are stacked. FIG. 11 illustrates a sectional view of an example of a pixel structure according to Embodiment 4.

The pixel structure according to Embodiment 4 has, on the side of the pixel chip 56, a three-dimensional stacked structure in which the SPAD element 51, the quench circuit 53, and the pulse shaping circuit 54 are stacked. In such a three-dimensional stacked structure, a configuration is provided in which the resistive element 81 and a contact section 82 are provided between the SPAD element 51, and the quench circuit 53 and the pulse shaping circuit 54. Specifically, the SPAD element 51, and the quench circuit 53 and the pulse shaping circuit 54 are electrically coupled to each other via the resistive element 81 and the contact section 82.

In a case of the pixel structure according to Embodiment 4 also, it is possible to achieve working and effects similar to those in the case of the pixel structure according to Embodiment 3. That is, it is possible to completely separate the capacitance of the pixel section between the side of the SPAD element 51 and the side of the quench circuit 53 and the pulse shaping circuit 54. It is therefore possible to further reduce electric power consumption of the light receiving device 30, as compared with the case of Embodiment 2.

### Embodiment 5

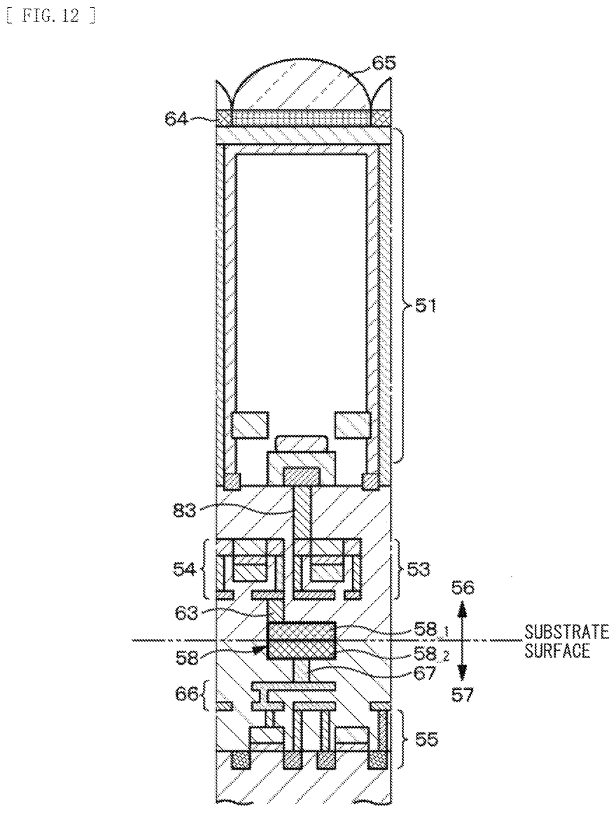

Embodiment 5 is a modification of Embodiment 1. Embodiment 5 is an example in which a contact section related to the pixel is directly electrically coupled to the transistor formation back surface side. FIG. 12 illustrates a sectional view of an example of a pixel structure according to Embodiment 5.

The pixel structure according to Embodiment 5 has a structure (Face to Back) in which the front surface side of the pixel chip 56 (the front surface side of the SPAD element 51) and the transistor formation back surface side of the circuit chip 57 are opposed to each other and bonded to each other. In such a structure, a configuration is provided in which a contact section 83 related to the SPAD element 51 is directly electrically coupled to the transistor formation back surface side.

In a case of the pixel structure according to Embodiment 5, a transistor formation layer is not penetrated, unlike the contact section 62 (see FIG. 6) of the pixel structure according to Embodiment 1. It is therefore possible to achieve both a reduction in electric power consumption and a reduction in circuit area.

### Embodiment 6

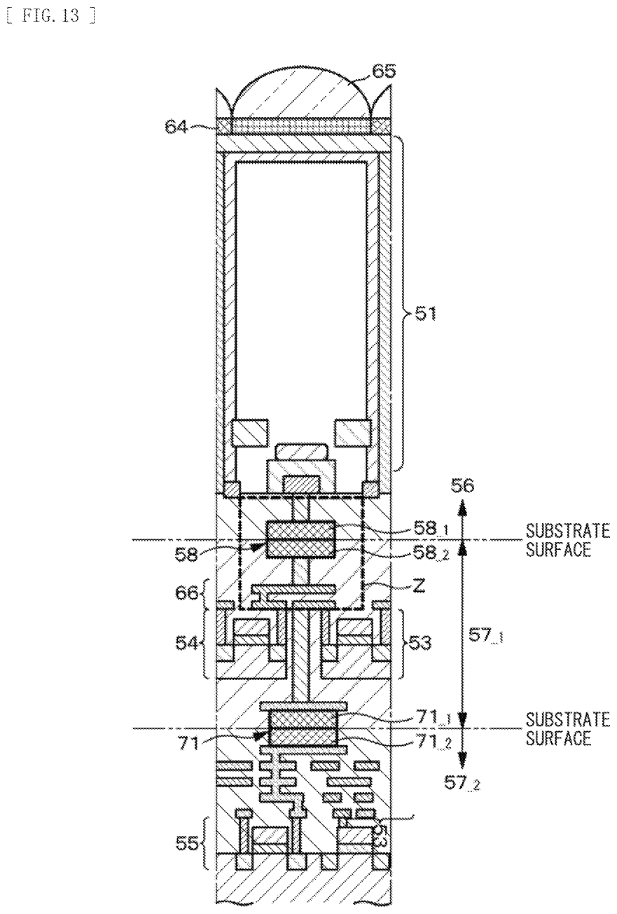

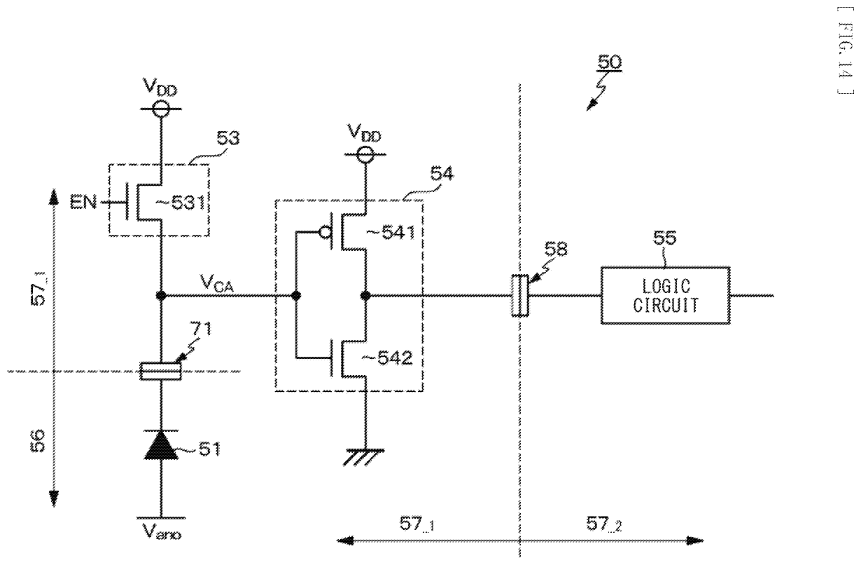

Embodiment 6 is an example of three-layered stacked structure in which the circuit chip 57 includes two semiconductor chips (circuit chips). FIG. 13 illustrates a sectional view of an example of a pixel structure according to Embodiment 6. FIG. 14 illustrates an equivalent circuit diagram of a pixel having the pixel structure according to Embodiment 6.

The pixel structure according to Embodiment 6 includes the circuit chip 57 including two semiconductor chips, that is, a first circuit chip 571 and a second circuit chip 57_2, and the quench circuit 53, therefore having the three-layered stacked chip structure. In this three-layered stacked chip structure, the SPAD element 51 is provided in the pixel chip 56, the quench circuit 53 and the pulse shaping circuit 54 are provided in the first circuit chip 57_1, and the logic circuit 55 is provided in the second circuit chip 57_2.

That is, the pixel structure according to Embodiment 6 has a structure in which, in the circuit chip 57 including the first circuit chip 571 and the second circuit chip 57_2, the quench circuit 53 and the pulse shaping circuit 54, and the logic circuit 55 are stacked across the first circuit chip 57_1 and the second circuit chip 572 in the direction perpendicular to the substrate surface.

The pixel chip 56 and the first circuit chip 571 are disposed with their surfaces opposed to each other and are electrically coupled to each other via the Cu—Cu junction section 58 of direct junction of the Cu electrode 58_1 and the Cu electrode 58_2. The first circuit chip 57_1 and the second circuit chip 572 are electrically coupled to each other via a Cu—Cu junction section 71 of direct junction of a Cu electrode 71_1 and a Cu electrode 71_2.

As described above, the pixel structure according to Embodiment 6 has the three-layered stacked chip structure in which the pixel chip 56, the first circuit chip 57_1, and the second circuit chip 57_2 are stacked. In such a three-layered stacked chip structure, a structure is provided in which the quench circuit 53 and the pulse shaping circuit 54, and the logic circuit 55 are stacked across the first circuit chip 57_1 and the second circuit chip 57_2 on the side of the circuit chip 57. This makes it possible to simplify the wiring structure of the wiring layer 66 that electrically couples the first circuit chip 57_1 to the pixel chip 56. As a result, it is possible to reduce the capacitance of the coupling section (a region Z surrounded by a thick broken line in the drawing) including the Cu—Cu junction section 58 and to reduce the signal amplitude at and after the coupling section. It is therefore possible to reduce electric power consumption of the light receiving device 30.

### Embodiment 7

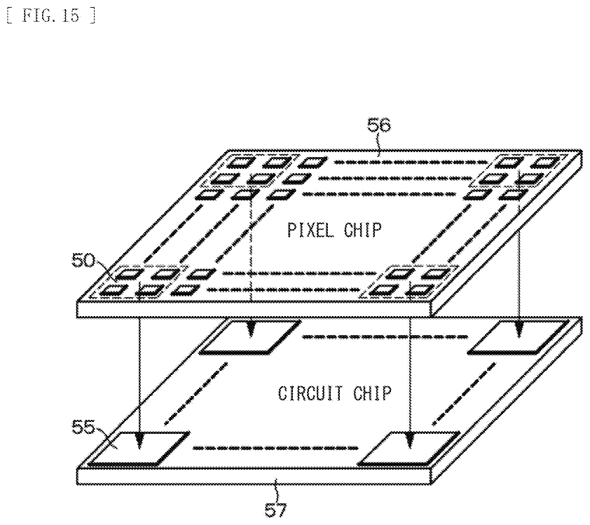

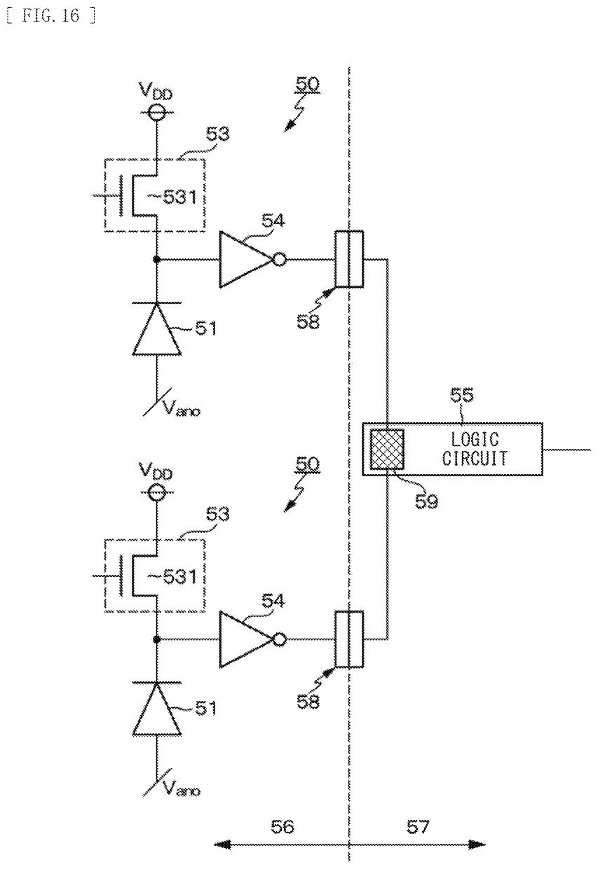

Embodiment 7 is an example of a stacked chip structure in which the one logic circuit 55 on the circuit chip 57 is shared by multiple pixels 50 on the pixel chip 56. FIG. 15 illustrates an exploded perspective view of an example of the stacked chip structure according to Embodiment 7. FIG. 16 illustrates a circuit diagram of an example of pixel sharing according to Embodiment 7.

In the pixel chip 56, an analog circuit section including the quench circuit 53 and the pulse shaping circuit 54 is provided in pixel units together with the SPAD element 51 which is the light receiving element. In the circuit chip 57, a digital circuit section including the logic circuit 55 is provided. Here, as illustrated in FIG. 15, a configuration is provided in which one one digital circuit section on the circuit chip 57, specifically, the logic circuit 55, is shared by an analog circuit section including four pixels 50 on the pixel chip 56. It is to be noted that the number of the pixels 50 sharing the one logic circuit 55 on the circuit chip 57 is not limited to four, and may be two pixels, three pixels, or five or more pixels. In order to achieve pixel sharing, a logic circuit 59 is provided at an input stage of the logic circuit 55. The logic circuit 59 includes an AND circuit, an OR circuit, an XOR circuit, a switch circuit, and the like.

### Modifications

Although the technology according to the present disclosure has been described above on the basis of the preferred embodiments, the technology according to the present disclosure is not limited to such embodiments. The configuration and the structure of the light receiving device and the distance measuring apparatus described above in the embodiments are examples and are modifiable as appropriate.

### Application Examples of Technology According to Present Disclosure

The technology according to the present disclosure is applicable to various products. More specific application examples are described below. For example, the technology according to the present disclosure may be achieved in the form of a distance measuring apparatus to be mounted on a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

### [Mobile Body]

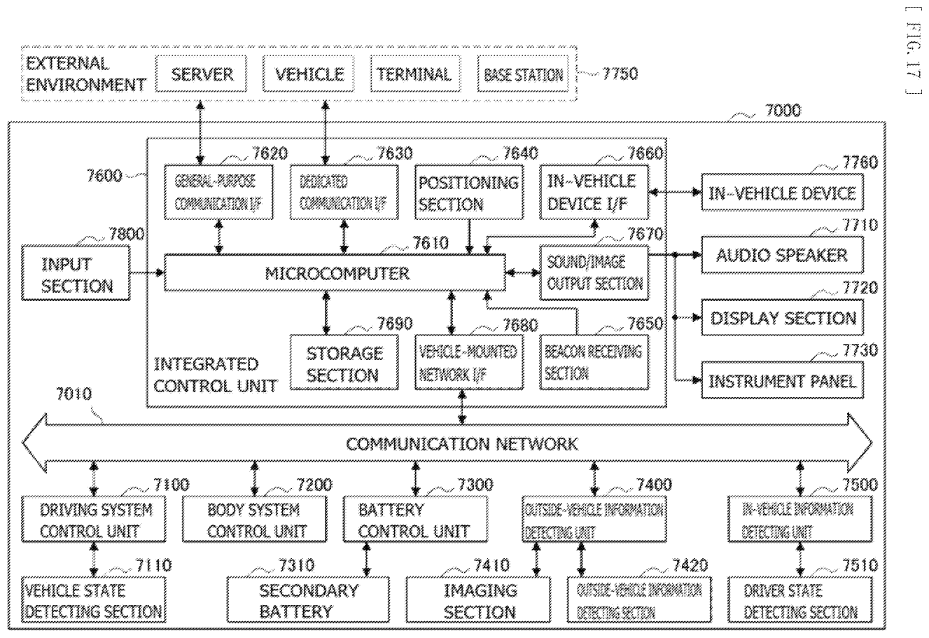

FIG. 17 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 17, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 17 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

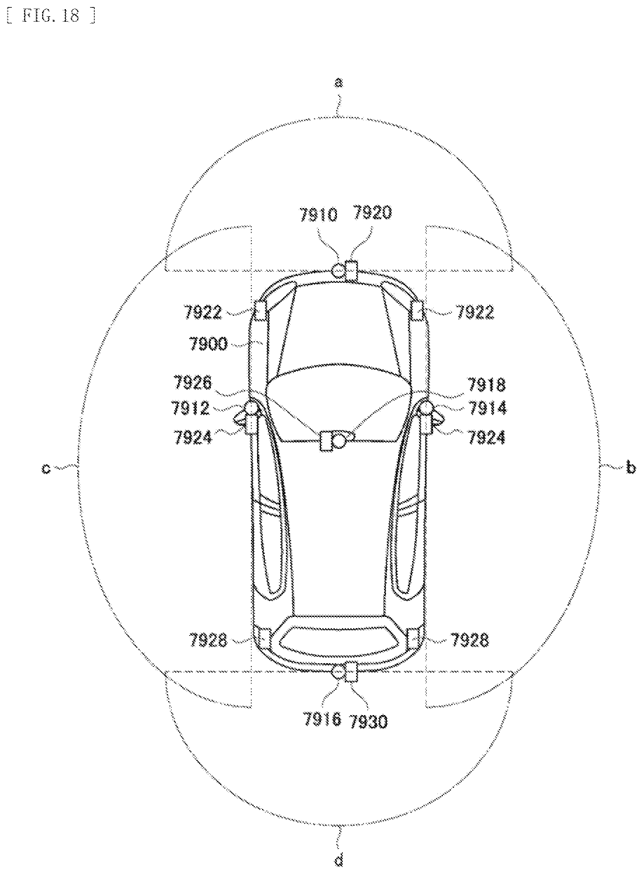

FIG. 18 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 17, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication IF that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 17, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 17 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

An example of the vehicle control system to which the technology according to the present disclosure is applicable has been described above. With the technology according to the present disclosure, for example, in a case where the imaging section 7410 or the outside-vehicle information detecting section 7420 among the components described above includes a ToF camera (a ToF sensor), it is possible to use, as the ToF camera, the light receiving device according to the embodiment described above that makes it possible to reduce electric power consumption. Accordingly, mounting the light receiving device as the ToF camera of the distance measuring apparatus makes it possible to construct a vehicle control system with low electric power consumption.

### <Possible Configurations of Present Disclosure>

It is to be noted that the present disclosure may also have the following configurations.

### <<A. Light Receiving Device>>

### [A-01]

A light receiving device including
a stacked chip structure including a pixel chip and a circuit chip that are stacked, in which,
in the pixel chip, a light receiving element is provided, the light receiving element generating a signal in accordance with reception of a photon, and
in the circuit chip, a transistor circuit section that is included in a readout circuit is disposed along a direction perpendicular to a substrate surface of the circuit chip with respect to an electrical coupling section between the pixel chip and the circuit chip, the readout circuit reading the signal generated by the light receiving element.

### [A-02]

The light receiving device according to [A-01] described above, in which the light receiving element includes an avalanche photodiode that operates in a Geiger mode.

### [A-03]

The light receiving device according to [A-02] described above, in which the light receiving element includes a single-photon avalanche diode.

### [A-04]

The light receiving device according to any one of [A-01] to [A-03] described above, in which
the readout circuit includes multiple transistor circuit sections, and
the multiple transistor circuit sections are provided to be stacked on each other in the circuit chip.

### [A-05]

The light receiving device according to [A-04] described above, in which
the multiple transistor circuit sections include a pulse shaping circuit and a logic circuit, the pulse shaping circuit shaping a pulse signal outputted from the light receiving element, the logic circuit processing the pulse signal shaped by the pulse shaping circuit, and
the pulse shaping circuit and the logic circuit are provided to be stacked on each other in the circuit chip.

### [A-06]

The light receiving device according to [A-05] described above, in which
in the pixel chip, a quench circuit is provided, the quench circuit suppressing avalanche multiplication of the light receiving element, and
the quench circuit is provided to be stacked with respect to the light receiving element in the pixel chip.

### [A-07]

The light receiving device according to any one of [A-01] to [A-03] described above, in which
the multiple transistor circuit sections include a pulse shaping circuit and a logic circuit, the pulse shaping circuit shaping a pulse signal outputted from the light receiving element, the logic circuit processing the pulse signal shaped by the pulse shaping circuit,
in the pixel chip, a quench circuit and the pulse shaping circuit are provided to be stacked with respect to the light receiving element, the quench circuit suppressing avalanche multiplication of the light receiving element, and
in the circuit chip, the logic circuit is provided.

### [A-08]

The light receiving device according to [A-07] described above, in which, in the pixel chip, the light receiving element, and the quench circuit and the pulse shaping circuit are electrically coupled to each other via a resistive element.

### [A-09]

The light receiving device according to [A-08] described above, in which, in the pixel chip, the resistive element is electrically coupled to the quench circuit and the pulse shaping circuit via a contact section.

### [A-10]

The light receiving device according to any one of [A-01] to [A-09] described above, in which the electrical coupling section between the pixel chip and the circuit chip includes a junction section of direct junction using a Cu electrode.

### [A-11]

The light receiving device according to [A-05] described above, in which
the circuit chip includes two semiconductor chips that are stacked,
the pulse shaping circuit is provided in one of the two semiconductor chips, and
the logic circuit is provided in another of the two semiconductor chips.

### [A-12]

The light receiving device according to [A-11] described above, in which the two semiconductor chips are electrically coupled to each other via a junction section using a Cu electrode.

### [A-13]

The light receiving device according to [A-07] described above, in which,
in the pixel chip, an analogue circuit section is provided in pixel units together with the light receiving element, the analogue circuit section including the quench circuit,
in the circuit chip, a digital circuit section is provided, the digital circuit section including the logic circuit, and
the one digital circuit section on the circuit chip is shared by the analogue circuit section including multiple pixels on the pixel chip.

### [A-14]

The light receiving device according to any one of [A-01] to [A-13] described above, in which a pixel including the light receiving element has a back-illuminated pixel structure that takes in light applied from a substrate back surface side in a case where a side, of the pixel chip, on which a wiring layer is provided is regarded as a substrate front surface side.

### <<B. Distance Measuring Apparatus>>

### [B-01]

A distance measuring apparatus including:
a light source unit that applies light to a distance measurement target; and
a light receiving device that receives reflected light from the distance measurement target, the reflected light being based on the light applied from the light source unit, in which
the light receiving device includes
   a stacked chip structure including a pixel chip and a circuit chip that are stacked,
   in the pixel chip, a light receiving element is provided, the light receiving element generating a signal in accordance with reception of a photon, and
   in the circuit chip, a circuit section that is included in a readout circuit is disposed along a direction perpendicular to a substrate surface of the circuit chip with respect to an electrical coupling section between the pixel chip and the circuit chip, the readout circuit reading the signal generated by the light receiving element.

### [B-02]

The distance measuring apparatus according to [B-01] described above, in which the light receiving element includes an avalanche photodiode that operates in a Geiger mode.

### [B-03]

The distance measuring apparatus according to [B-02] described above, in which the light receiving element includes a single-photon avalanche diode.

### [B-04]

The distance measuring apparatus according to any one of [B-01] to [B-03] described above, in which
the readout circuit includes multiple transistor circuit sections, and
the multiple transistor circuit sections are provided to be stacked on each other in the circuit chip.

### [B-05]

The distance measuring apparatus according to [B-04] described above, in which
the multiple transistor circuit sections include a pulse shaping circuit and a logic circuit, the pulse shaping circuit shaping a pulse signal outputted from the light receiving element, the logic circuit processing the pulse signal shaped by the pulse shaping circuit, and
the pulse shaping circuit and the logic circuit are provided to be stacked on each other in the circuit chip.

### [B-06]

The distance measuring apparatus according to [B-05] described above, in which,
in the pixel chip, a quench circuit is provided, the quench circuit suppressing avalanche multiplication of the light receiving element, and
the quench circuit is provided to be stacked with respect to the light receiving element in the pixel chip.

### [B-07]

The distance measuring apparatus according to any one of [B-01] to [B-03] described above, in which
the multiple transistor circuit sections include a pulse shaping circuit and a logic circuit, the pulse shaping circuit shaping a pulse signal outputted from the light receiving element, the logic circuit processing the pulse signal shaped by the pulse shaping circuit,
in the pixel chip, a quench circuit and the pulse shaping circuit are provided to be stacked with respect to the light receiving element, the quench circuit suppressing avalanche multiplication of the light receiving element, and
in the circuit chip, the logic circuit is provided.

### [B-08]

The distance measuring apparatus according to [B-07] described above, in which, in the pixel chip, the light receiving element, and the quench circuit and the pulse shaping circuit are electrically coupled to each other via a resistive element.

### [B-09]

The distance measuring apparatus according to [B-08] described above, in which, in the pixel chip, the resistive element is electrically coupled to the quench circuit and the pulse shaping circuit via a contact section.

### [B-10]

The distance measuring apparatus according to any one of [B-01] to [B-09] described above, in which the electrical coupling section between the pixel chip and the circuit chip includes a junction section of direct junction using a Cu electrode.

### [B-11]

The distance measuring apparatus according to [B-05] described above, in which
the circuit chip includes two semiconductor chips that are stacked,
the pulse shaping circuit is provided in one of the two semiconductor chips, and
the logic circuit is provided in another of the two semiconductor chips.

### [B-12]

The distance measuring apparatus according to [B-11] described above, in which the two semiconductor chips are electrically coupled to each other via a junction section using a Cu electrode.

### [B-13]

The distance measuring apparatus according to [B-07] described above, in which,
in the pixel chip, an analogue circuit section is provided in pixel units together with the light receiving element, the analogue circuit section including the quench circuit,
in the circuit chip, a digital circuit section is provided, the digital circuit section including the logic circuit, and
the one digital circuit section on the circuit chip is shared by the analogue circuit section including multiple pixels on the pixel chip.

### [B-14]

The distance measuring apparatus according to any one of [B-01] to [B-13] described above, in which a pixel including the light receiving element has a back-illuminated pixel structure that takes in light applied from a substrate back surface side in a case where a side, of the pixel chip, on which a wiring layer is provided is regarded as a substrate front surface side.

This application claims the priority on the basis of Japanese Patent Application No. 2020-179608 filed on Oct. 27, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A light detecting device comprising:
an avalanche photodiode disposed in a first layer;
readout circuitry disposed in a second layer and a third layer, the readout circuitry including
quench circuitry coupled to the avalanche photodiode,
pulse shape circuitry coupled to the avalanche photodiode, and
logic circuitry coupled to the pulse shape circuitry,
wherein the first layer, the second layer, and the third layer are stacked on each other,
wherein a portion of the quench circuitry is disposed in the second layer, and
wherein the logic circuitry is disposed in the third layer.

2. The light detecting device according to claim 1, wherein the avalanche photodiode operates in a Geiger mode.

3. The light detecting device according to claim 2, wherein the avalanche photodiode is a single-photon avalanche diode.

4. The light detecting device according to claim 1, wherein
the readout circuitry includes multiple transistor circuit sections, and
the multiple transistor circuit sections are stacked on each other in a stacking direction.

5. The light detecting device according to claim 4, wherein
the multiple transistor circuit sections include the pulse shape circuitry and the logic circuitry, the pulse shape circuitry configured to shape a pulse signal output from the avalanche photodiode, the logic circuitry configured to process the pulse signal output that is shaped by the pulse shaping circuitry.

6. The light detecting device according to claim 5, wherein
the quench circuitry is configured to suppress avalanche multiplication of the avalanche photodiode.

7. (canceled)

8. The light detecting device according to claim 1, wherein the avalanche photodiode, the quench circuitry, and the pulse shape circuitry are stacked in a stacking direction, and wherein the avalanche photodiode, the quench circuitry, and the pulse shape circuitry are electrically coupled to each other by an electrical conductor that extends in the stacking direction.

9. The light detecting device according to claim 8, wherein the electrical conductor is electrically coupled to the quench circuitry and the pulse shape circuitry by a contact section.

10. The light detecting device according to claim 1, wherein an interface between the second layer and the third layer includes a junction using a stacked copper-to-copper (Cu—Cu) connection.

11. The light detecting device according to claim 1, wherein
wherein a first semiconductor chip includes the first layer and the second layer,
wherein a second semiconductor chip includes the third layer.

12. The light detecting device according to claim 11, wherein the first semiconductor chip and the second semiconductor chip are electrically coupled to each other via a junction using a copper electrode.

13. The light detecting device according to claim 1, wherein,
an analogue circuit section is provided in pixel units together with the avalanche photodiode, the analogue circuit section including the quench circuitry,
a digital circuit section includes the logic circuitry, and
the digital circuit section is shared by the analogue circuit section including multiple pixels.

14. The light detecting device according to claim 1, wherein the avalanche photodiode has a back-illuminated pixel structure that takes in light applied from a substrate back surface side in a case where a side, on which a wiring layer is provided, is regarded as a substrate front surface side.

15. A distance measuring apparatus comprising:
a light source unit that applies light to a distance measurement target; and
a light receiving device that receives reflected light from the distance measurement target, the reflected light being based on the light applied from the light source unit, wherein
the light receiving device includes
an avalanche photodiode disposed in a first layer;
readout circuitry disposed in a second layer and a third layer, the readout circuitry including
quench circuitry coupled to the avalanche photodiode,
pulse shape circuitry coupled to the avalanche photodiode, and
logic circuitry coupled to the pulse shape circuitry,
wherein the first layer, the second layer, and the third layer are stacked on each other,
wherein a portion of the quench circuitry is disposed in the second layer, and
wherein the logic circuitry is disposed in the third layer.

16. The distance measuring apparatus according to claim 15, wherein the avalanche photodiode, the quench circuitry, and the pulse shape circuitry are stacked in a stacking direction, and wherein the avalanche photodiode, the quench circuitry, and the pulse shape circuitry are electrically coupled to each other by an electrical conductor that extends in the stacking direction.

17. The light detecting device according to claim 1, wherein the logic circuitry includes a counter.

18. The light detecting device according to claim 1, wherein the logic circuitry includes a time-to-digital converter (TDC).

19. The light detecting device according to claim 1, wherein the second layer includes one or more transistors with a light receiving side facing the avalanche photodiode and a second side opposite to the light receiving side and facing away from the avalanche photodiode, and wherein the one or more transistors are electrically connected to the avalanche photodiode on the second side.

20. The light detecting device according to claim 19, wherein the second layer includes a wiring layer disposed adjacent to the second side.

21. The light detecting device according to claim 1, wherein the second layer includes a PMOS transistor and an NMOS transistor.
